(19) United States
(12) Patent Application Publication
(10) Pub. No.: US 2015/0162301 A1
(43) Pub. Date: Jun. 11, 2015

(54) METHOD FOR FABRICATING SEMICONDUCTOR PACKAGE

(71) Applicant: Siliconware Precision Industries Co., Ltd., Taichung (TW)

(72) Inventors: Huei-Nuan Huang, Taichung (TW); Mu-Hsuan Chan, Taichung (TW); Chun-Tang Lin, Taichung (TW)

(73) Assignee: Siliconware Precision Industries Co., Ltd., Taichung (TW)

(21) Appl. No.: 14/276,320

(22) Filed: May 13, 2014

(30) Foreign Application Priority Data
Dec. 9, 2013 (TW) 102145088

(51) Int. Cl. H01L 23/00; H01L 21/78; H01L 21/56

(52) U.S. Cl. CPC H01L 24/81; H01L 21/56; H01L 21/78; H01L 2924/3511; H01L 2924/3841

(57) ABSTRACT

A method for fabricating a semiconductor package is provided, which includes the steps of: providing a carrier having at least a semiconductor chip disposed thereon, the semiconductor chip having a first surface attached to the carrier, and an opposite second surface having a plurality of first conductive elements thereon; disposing an interposer on the first conductive elements, wherein the interposer has opposite third and fourth surfaces, the interposer is disposed on the first conductive elements via the third surface, and a plurality of conductive posts are embedded in the interposer and electrically connected to the third surface; forming an encapsulant on the carrier for encapsulating the semiconductor chip and the interposer; removing a portion of the encapsulant from the upper surface thereof and a portion of the interposer from the fourth surface thereof to expose ends of the conductive posts; and removing the carrier, thereby improving the connection quality between the semiconductor chip and the interposer.

### BACKGROUND OF THE INVENTION

1. Field of the Invention

The present invention relates to methods for fabricating semiconductor packages, and more particularly, to a method for fabricating a semiconductor package having an interposer.

2. Description of Related Art

Flip-chip technologies facilitate to reduce chip packaging sizes and shorten signal transmission paths and therefore have been widely used for chip packaging. Various types of packages such as chip scale packages (CSPs), direct chip attached (DCA) packages and multi-chip module (MCM) packages can be achieved through flip-chip technologies.

In a flip-chip packaging process, a big CTE (Coefficient of Thermal Expansion) mismatch between a chip and a packaging substrate adversely affects the formation of joints between conductive bumps of the chip and contacts of the packaging substrate, thus easily resulting in delamination of the conductive bumps from the packaging substrate. On the other hand, along with increased integration of integrated circuits, a CIE mismatch between a chip and a packaging substrate induces more thermal stresses and leads to more serious warpage, thereby reducing the product reliability and easily resulting in failure of a reliability test.

In view of the above-described drawbacks, an interposer made of a semiconductor material is provided. That is, a through silicon interposer is disposed between a packaging substrate and a semiconductor chip. Since the through silicon interposer is close in material to the semiconductor chip, the above-described drawbacks caused by a CTE mismatch can be effectively overcome.

FIG. 1 is a schematic cross-sectional view showing a conventional package structure having a through silicon interposer. Referring to FIG. 1, at least a semiconductor chip 11 is disposed on a packaging substrate 13 through a through silicon interposer 12. In addition to overcome the above-described drawbacks, such a structure facilitates to reduce the area of the package structure.

For example, the packaging substrate 13 generally has a minimum line width/pitch of 12/12 um. If the semiconductor chip 11 is directly mounted on the packaging substrate 13, when the I/O count of the semiconductor chip 11 increases, the area of the packaging substrate 13 must also be increased to provide sufficient electrical connection with the semiconductor chip 11. On the other hand, in the package structure of FIG. 1, the through silicon interposer 12 can have a line width/pitch of 3/3 um or smaller through a semiconductor process. As such, when the I/O count of the semiconductor chip 11 increases, the area of the through silicon interposer 12 can provide sufficient electrical connection with the semiconductor chip 11. Further, the fine line width/pitch characteristic of the through silicon interposer 12 facilitates to shorten the electrical transmission path and increase the electrical transmission speed.

However, in such a package structure, warpage of the through silicon interposer easily occurs to cause solder bridging (as shown in FIG. 1) or non-wetting, thus leading to short or open circuit and reducing the product reliability.

Therefore, there is a need to provide a method for fabricating a semiconductor package so as to overcome the above-described drawbacks.

### SUMMARY OF THE INVENTION

In view of the above-described drawbacks, the present invention provides a method for fabricating a semiconductor package, which comprises the steps of: providing a carrier having at least a semiconductor chip disposed thereon, wherein the semiconductor chip has a first surface attached to the carrier, and a second surface opposite to the first surface and having a plurality of first conductive elements formed thereon; disposing an interposer on the first conductive elements, wherein the interposer has opposite third and fourth surfaces, the interposer is disposed on the first conductive elements via the third surface thereof, and a plurality of conductive posts are embedded in the interposer and electrically connected to the third surface of the interposer; forming an encapsulant on the carrier for encapsulating the semiconductor chip and the interposer, wherein the encapsulant has a lower surface adjacent to the carrier and an upper surface opposite to the lower surface; removing a portion of the encapsulant from the upper surface thereof and a portion of the interposer from the fourth surface thereof so as to expose an end of each of the conductive posts; and removing the carrier.

After removing portions of the interposer and the encapsulant, the method can further comprise forming a redistribution layer on the fourth surface of the interposer and the upper surface of the encapsulant, wherein the redistribution layer is electrically connected to the conductive posts. Further, the method can comprise forming a plurality of second conductive elements on the redistribution layer.

After removing portions of the interposer and the encapsulant, the method can further comprise performing a singulation process. The encapsulant can be made of a molding compound or a dry film, and portions of the interposer and the encapsulant can be removed by grinding.

In the above-described method, the first conductive elements and the second conductive elements can be solder balls, and the carrier can be a tape.

In the above-described method, the conductive posts can be electrically connected to a circuit layer formed on the third surface of the interposer, and the semiconductor chip can be a known good die.

Therefore, by encapsulating the interposer and the semiconductor chip with the encapsulant, the present invention can effectively prevent warpage of the interposer and improve the connection quality between the interposer and the semiconductor chip. Further, by forming the fan-out redistribution layer outside the interposer, the present invention can effectively reduce the size of the interposer, increase the I/O count and reduce the overall cost. Furthermore, the present invention can reconfigure a plurality of semiconductor chips in a semiconductor package so as to increase the overall yield.

### BRIEF DESCRIPTION OF DRAWINGS

FIG. 1 is a schematic cross-sectional views showing a conventional package structure having a through silicon interposer; and

FIGS. 2A to 2I are schematic cross-sectional views showing a method for fabricating a semiconductor package according to the present invention.

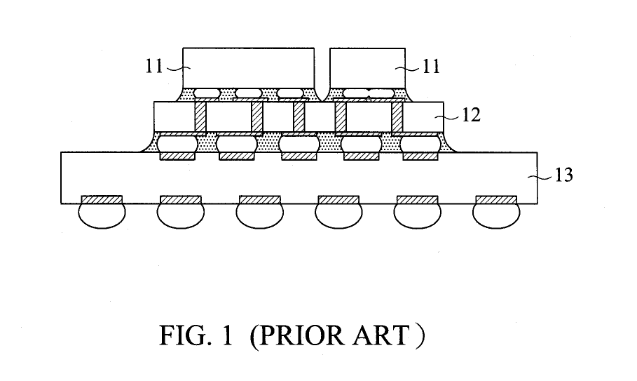

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention. Further, terms such as “upper”, “lower”, “a” etc. are merely for illustrative purposes and should not be construed to limit the scope of the present invention.

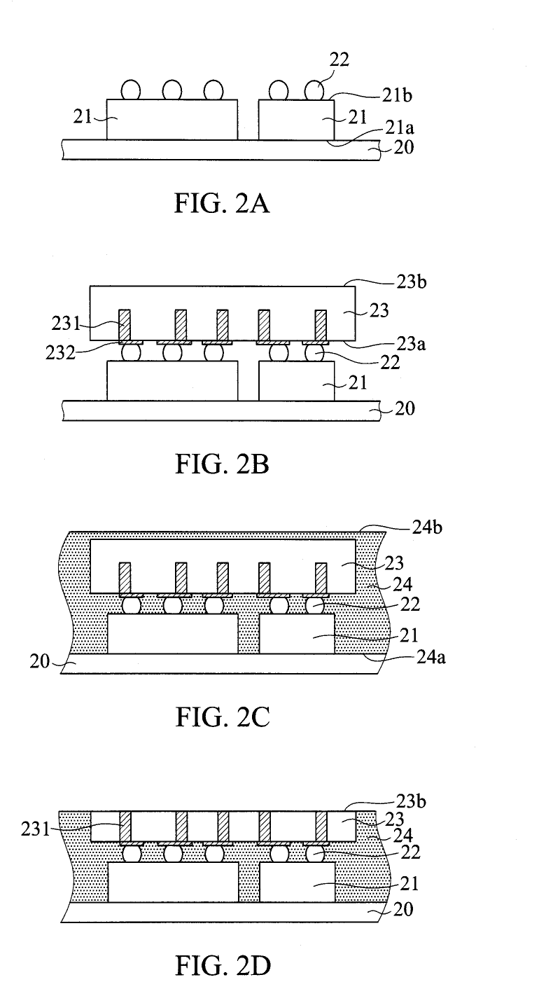

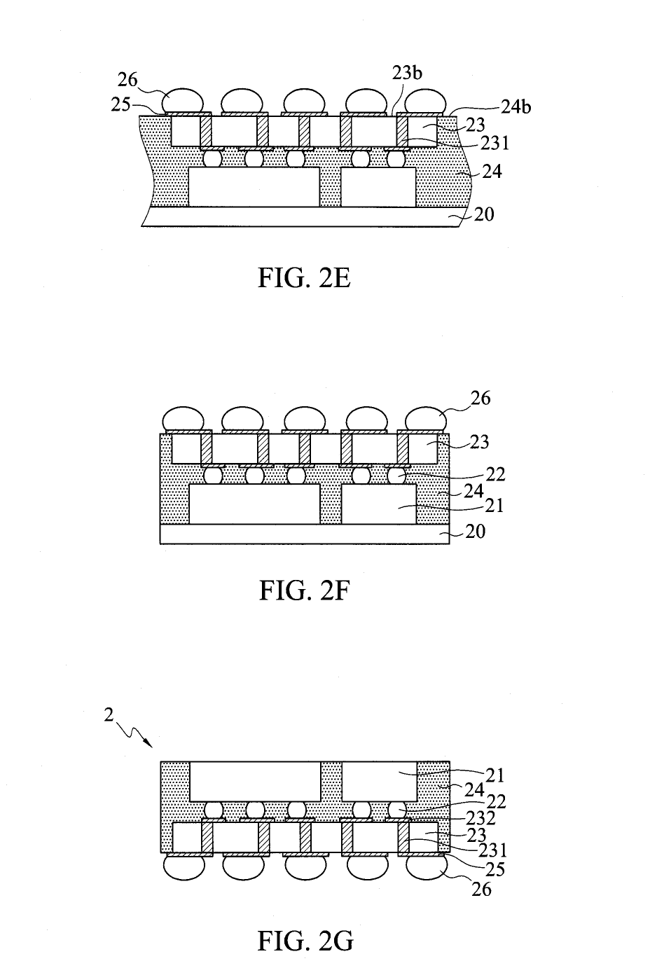

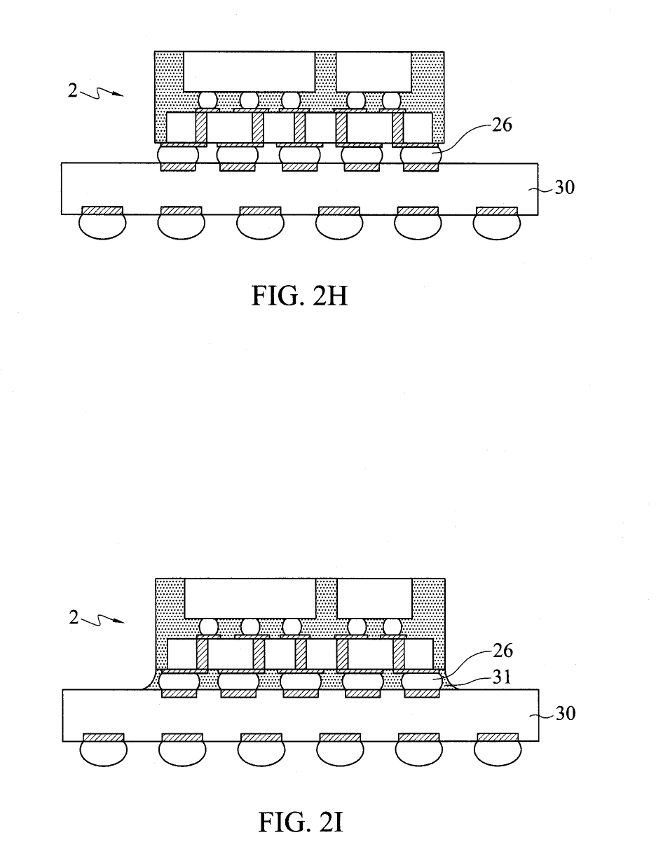

FIGS. 2A to 2I are schematic cross-sectional views showing a method for fabricating a semiconductor package according to the present invention.

Referring to FIG. 2A, a carrier 20 is provided with at least a semiconductor chip 21 disposed thereon. The semiconductor chip 21 has a first surface 21a attached to the carrier 20, and a second surface 21b opposite to the first surface 21a and having a plurality of first conductive elements 22 formed thereon. The carrier 20 can be a tape. The first conductive elements 22 can be solder balls. The semiconductor chip 21 can be a known good die.

Referring to FIG. 2B, an interposer 23 is disposed on the first conductive elements 22. The interposer 23 has opposite third and fourth surfaces 23a, 23b. The interposer 23 is disposed on the first conductive elements 22 via the third surface 23a thereof, and a plurality of conductive posts 231 are embedded in the interposer 23 and electrically connected to the third surface 23a of the interposer 23. In particular, the conductive posts 231 are electrically connected to a circuit layer 232 formed on the third surface 23a of the interposer 23.

Referring to FIG. 2C, an encapsulant 24 is formed on the carrier 20 to encapsulate the semiconductor chip 21 and the interposer 23. The encapsulant 24 has a lower surface 24a adjacent to the carrier 20 and an upper surface 24b opposite to the lower surface 24a. The encapsulant 24 can be made of a molding compound or a dry film.

Referring to FIG. 2D, portions of the interposer 23 and the encapsulant 24 are removed by grinding from the fourth surface 23b of the interposer 23 so as to expose one ends of the conductive posts 231.

Referring to FIG. 2E, a redistribution layer 25 is formed on the fourth surface 23b of the interposer 23 and the upper surface 24b of the encapsulant 24 and electrically connected to the conductive posts 231. Further, a plurality of second conductive elements 26 are formed on the redistribution layer 25. The second conductive elements 26 can be solder balls.

Referring to FIG. 2F, a singulation process is performed.

Referring to FIG. 2G, the carrier 20 is removed to form a semiconductor package 2.

Referring to FIGS. 2H to 2I, the semiconductor package 2 is further disposed on a packaging substrate 30 through the second conductive elements 26, and an underfill 31 is formed between the semiconductor package 2 and the packaging substrate 30 for encapsulating the second conductive elements 26.

Therefore, by encapsulating the interposer and the semiconductor chip with the encapsulant, the present invention can effectively prevent warpage of the interposer and improve the connection quality between the interposer and the semiconductor chip. Further, by forming the fan-out redistribution layer outside the interposer, the present invention can effectively reduce the size of the interposer, increase the I/O count and reduce the overall cost. Furthermore, the present invention can reconfigure a plurality of semiconductor chips in a semiconductor package so as to increase the overall yield.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A method for fabricating a semiconductor package, comprising the steps of:
providing a carrier having at least a semiconductor chip disposed thereon, wherein the semiconductor chip has a first surface attached to the carrier, and a second surface opposite to the first surface and having a plurality of first conductive elements formed thereon;
disposing an interposer on the first conductive elements, wherein the interposer has opposite third and fourth surfaces, the interposer is disposed on the first conductive elements via the third surface thereof, and a plurality of conductive posts are embedded in the interposer and electrically connected to the third surface of the interposer;
forming an encapsulant on the carrier for encapsulating the semiconductor chip and the interposer, wherein the encapsulant has a lower surface adjacent to the carrier and an upper surface opposite to the lower surface;
removing a portion of the encapsulant from the upper surface thereof and a portion of the interpose from the fourth surface thereof so as to expose an end of each of the conductive posts; and
removing the carrier.

2. The method of claim 1, after removing portions of the interposer and the encapsulant, further comprising forming a redistribution layer on the fourth surface of the interposer and the upper surface of the encapsulant, the redistribution layer being electrically connected to the conductive posts.

3. The method of claim 2, further comprising forming a plurality of second conductive elements on the redistribution layer.

4. The method of claim 1, after removing portions of the interposer and the encapsulant, further comprising performing a singulation process.

5. The method of claim 1, wherein the encapsulant is made of a molding compound or a dry film.

6. The method of claim 1, wherein the removal of the portions of the interposer and the encapsulant is proformed by grinding.

7. The method of claim 3, wherein the first conductive elements and the second conductive elements are solder balls.

8. The method of claim 1, wherein the carrier is a tape.

9. The method of claim 1, wherein the conductive posts are electrically connected to a circuit layer formed on the third surface of the interposer.

10. The method of claim 1, wherein the semiconductor chip is a known good die.
